(19) United States
(12) Patent Application Publication
(10) Pub. No.: US 2025/0318240 A1
(43) Pub. Date: Oct. 9, 2025

(54) DUAL-STAGE SCHOTTKY BARRIER AND METHOD

(71) Applicant: Raytheon Company, Tewksbury, MA (US)

(72) Inventors: Jarrod Vaillancourt, South Hampton, NH (US); Christopher J. MacDonald, Medford, MA (US); William J. Davis, Hollis, NH (US)

(21) Appl. No.: 18/627,236

(22) Filed: Apr. 4, 2024

(51) Int. Cl. H01L 29/423; H01L 29/47; H01L 29/66; H01L 29/812

(52) U.S. Cl. CPC H10D 64/411; H10D 30/0612; H10D 30/6738; H10D 30/675; H10D 30/87; H10D 30/877; H10D 62/85; H10D 64/64

(57) ABSTRACT

A semiconductor device includes a dual-stage Schottky barrier. The dual-stage Schottky barrier includes a first stage and a second stage. The first stage is formed over a substrate stack and includes an upper layer having a length corresponding to a gate length for the device. The second stage is formed at least partially over the first stage and includes a contact segment having a length less than the gate length.

### TECHNICAL FIELD

This disclosure relates generally to semiconductor devices and device fabrication. More specifically, this disclosure relates to a dual-stage Schottky barrier and method.

### BACKGROUND

Many semiconductor devices, such as Field Effect Transistors (FETs), include Schottky barriers. For example, many FETs include a Schottky barrier between a semiconductor layer and a gate metal. However, typical manufacturing methods for Schottky barriers can often result in variations in their etched nitride sidewall angles or metal thickness such that the layers of the Schottky barriers are discontinuous. When this occurs, the gate metal is able to penetrate through the barrier layers to the underlying semiconductor layer. This can result in the gate metal reaching the 2D electron gas, which causes a significant rise in gate leakage and can lead to early device failure under operation.

### SUMMARY

This disclosure relates to a dual-stage Schottky barrier and method.

In a first embodiment, a semiconductor device includes a dual-stage Schottky barrier. The dual-stage Schottky barrier includes a first stage and a second stage. The first stage is formed over a substrate stack and includes an upper layer having a length corresponding to a gate length for the device. The second stage is formed at least partially over the first stage and includes a contact segment having a length less than the gate length.

In a second embodiment, a method includes forming a first stage of a dual-stage Schottky barrier over a substrate stack for a semiconductor device. The first stage includes an upper layer having a length corresponding to a gate length for the device. A second stage of the dual-stage Schottky barrier is formed at least partially over the first stage. The second stage includes a contact segment having a length less than the gate length.

In a third embodiment, a method includes forming a first stage of a dual-stage Schottky barrier over a substrate stack for a semiconductor device. The first stage includes an upper layer having a length corresponding to a gate length for the device. An early passivation layer is formed over the first stage. The early passivation layer is patterned and etched to partially expose the first stage. A second stage of the dual-stage Schottky barrier is formed at least partially over the first stage. The second stage includes a contact segment having a length less than the gate length.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example dual-stage Schottky barrier according to this disclosure;

FIGS. 2A-2B illustrate examples of the dual-stage Schottky barrier of FIG. 1 according to a first embodiment of this disclosure;

FIGS. 3A-3B illustrate examples of the dual-stage Schottky barrier of FIG. 1 according to a second embodiment of this disclosure;

FIGS. 4A-4B illustrate examples of the dual-stage Schottky barrier of FIG. 1 according to a third embodiment of this disclosure;

FIGS. 5A-5B illustrate examples of the dual-stage Schottky barrier of FIG. 1 according to a fourth embodiment of this disclosure;

FIGS. 6A-6B illustrate examples of the dual-stage Schottky barrier of FIG. 1 according to a fifth embodiment of this disclosure;

FIGS. 7A-7B illustrate examples of the dual-stage Schottky barrier of FIG. 1 according to a sixth embodiment of this disclosure; and

FIG. 8 illustrates an example method for forming a semiconductor device including a dual-stage Schottky barrier according to this disclosure.

### DETAILED DESCRIPTION

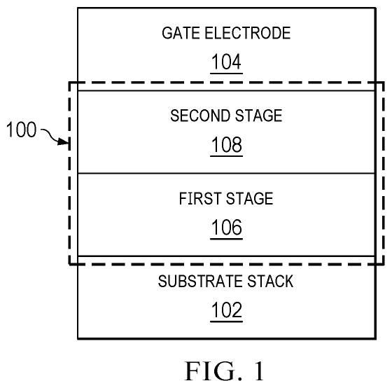

FIGS. 1 through 8, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, currently-implemented Schottky barriers are often formed with variations in their etched nitride sidewall angles due to manufacturing issues, which can result in the layers of such a Schottky barrier being discontinuous. For example, the metal layers may break at the corners due to thinning at the sidewalls. When this occurs, the gate metal may be able to penetrate through the barrier layers to a semiconductor layer, which allows the gate metal to reach the 2D electron gas and causes a significant rise in gate leakage. This can lead to early device failure under operation. This disclosure provides a dual-stage Schottky barrier and a method for forming such a barrier that ensure the gate metal is unable to leak through and make contact with the substrate stack. In this way, gate leakage can be minimized or eliminated, thereby increasing the lifetime of the device.

FIG. 1 illustrates an example dual-stage Schottky barrier 100 formed between a substrate stack 102 and a gate electrode 104 according to this disclosure. The embodiment of the dual-stage Schottky barrier 100 shown in FIG. 1 is for illustration only. Other embodiments of the dual-stage Schottky barrier 100 could be used without departing from the scope of this disclosure.

According to embodiments of this disclosure, the dual-stage Schottky barrier 100 includes a first stage 106 and a second stage 108. As described in more detail below, each of the stages 106 and 108 can include one or more layers of metals. For example, for some embodiments, the Schottky barrier 100 can include six metal layers. For these embodiments, the first stage 106 can include four metal layers and the second stage can include two metal layers. For a particular embodiment, the first stage 106 can include a first layer of nickel, a second layer of platinum, a third layer of nickel, and a fourth layer of platinum, while the second stage 108 can include a fifth layer of nickel and a sixth layer of platinum. However, it will be understood that each stage 106 and 108 may include any suitable number of metal layers and that the metal layers may each comprise any suitable material.

According to embodiments of this disclosure, the substrate stack 102 can include any suitable semiconductor structure and the gate electrode 104 can include any suitable contact material. For example, for some embodiments, the substrate stack 102 can include a substrate structure, a gallium nitride (GaN) layer, and an aluminum gallium nitride (AlGaN) layer, and the gate electrode 104 can include a layer of gold.

The first stage 106 of the dual-stage Schottky barrier 100 is formed over the substrate stack 102, and the second stage 108 of the dual-stage Schottky barrier 100 is formed over the first stage 106. The gate electrode 104 is formed over the second stage 108. As described in more detail below, an upper layer of the first stage 106 and at least a portion of a lower layer of the second stage 108 are configured to couple the stages 106 and 108 to each other. The length of the upper layer of the first stage 106, which corresponds to a gate length for the device that includes the Schottky barrier 100, is greater than the length of a contact segment of the lower layer of the second stage 108. The contact segment of the lower layer of the second stage 108 is a part of the lower layer that is in contact with the upper layer of the first stage 106. For some embodiments, the contact segment may include only a portion of the lower layer, while for other embodiments, the contact segment may include the entire lower layer. Thus, when the gate electrode 104 is deposited, if any of the material forming the gate electrode 104 leaks through or past the contact segment of the lower layer of the second stage 108, the longer dimension of the upper layer of the first stage 106 would prevent the material from reaching the substrate stack 102, resulting in an increase in the lifetime of the device.

Although FIG. 1 illustrates one example of a dual-stage Schottky barrier 100, various changes may be made to FIG. 1. For instance, the dual-stage Schottky barrier 100 may include any suitable number of additional stages. Also, note that the view shown in FIG. 1 is not to scale, especially with regard to the length dimensions of the stages 106 and 108.

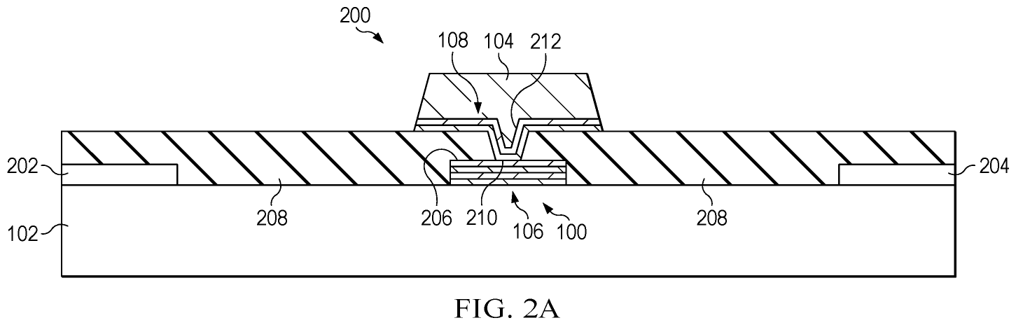

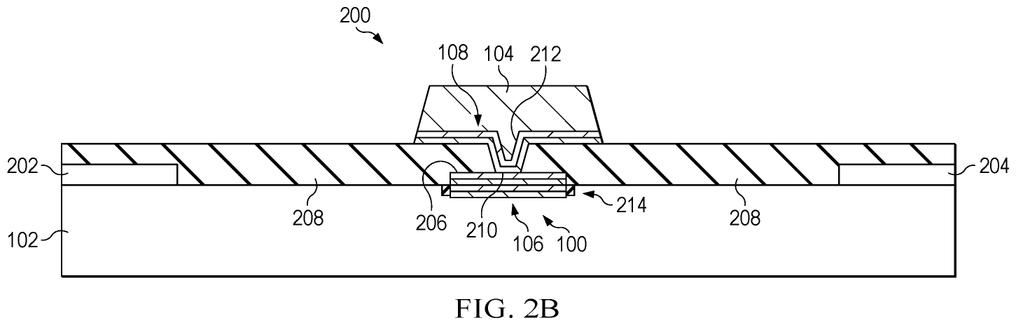

FIGS. 2A-2B illustrate examples of the dual-stage Schottky barrier 100 of FIG. 1 according to a first embodiment of this disclosure. According to the embodiment illustrated in FIGS. 2A-2B, a transistor 200 includes a source 202 and a drain 204, each formed on the substrate stack 102. The first stage 106 of the dual-stage Schottky barrier 100, including an upper layer 206, is formed over the substrate stack 102. As described above in connection with FIG. 1, the first stage 106 can include any suitable number of layers. For the particular embodiment illustrated in FIGS. 2A-2B, the first stage 106 includes four layers. Thus, for the illustrated embodiment, the fourth layer of the first stage 106 is the upper layer 206.

An early passivation layer 208 is formed over the source 202, the drain 204, and the first stage 106 of the dual-stage Schottky barrier 100. According to some embodiments, the early passivation layer 208 can include a layer of silicon nitride or other suitable material. After patterning and etching of the early passivation layer 208 to partially expose the first stage 106, the second stage 108 of the dual-stage Schottky barrier 100, including a contact segment 210, is formed over the partially exposed first stage 106 and the early passivation layer 208. For the illustrated embodiment, the second stage 108 also includes sidewalls 212 that are configured to receive the material of the gate electrode 104.

For the particular embodiment illustrated in FIGS. 2A-2B, the second stage 108 includes two layers. However, as described above in connection with FIG. 1, the second stage 108 can include any suitable number of layers. For this embodiment, the contact segment 210 includes a portion of the lower layer of the second stage 108. As shown in FIGS. 2A-2B, the contact segment 210 includes the portion of the first layer of the second stage 108 that is in contact with the upper layer 206 of the first stage 106. Thus, the upper layer 206 and the contact segment 210 are configured to couple the first stage 106 and the second stage 108 together. In addition, as shown, the upper layer 206 has a length that is greater than the length of the contact segment 210.

The gate electrode 104 is formed over the second stage 108 of the dual-stage Schottky barrier 100. Thus, as the upper layer 206 of the first stage 106 is longer than the contact segment 210 of the lower layer of the second stage 108, even if any of the material that forms the gate electrode 104, such as gold or other suitable material, leaks through the sidewalls 212 of the second stage 108, the first stage 106 of the dual-stage Schottky barrier 100 prevents the material from making contact with the substrate stack 102.

For the embodiment illustrated in FIG. 2A, the first stage 106 of the Schottky barrier 100 is formed on top of a planarized substrate stack 102. However, for the embodiment illustrated in FIG. 2B, a recess 214 is formed in the substrate stack 102, and the first stage 106 of the Schottky barrier 100 is formed at least partially in the recess 214. For this embodiment, while an additional manufacturing step is introduced, the transconductance in the material can be improved.

Although FIGS. 2A-2B illustrate examples of a dual-stage Schottky barrier 100, various changes may be made to FIGS. 2A-2B. For instance, the dual-stage Schottky barrier 100 may include any suitable number of additional stages. Also, note that the views shown in FIGS. 2A-2B are not to scale. In addition, for the embodiment illustrated in FIG. 2B, it will be understood that the first stage 106 may alternatively be fully formed within the recess 214 of the substrate stack 102.

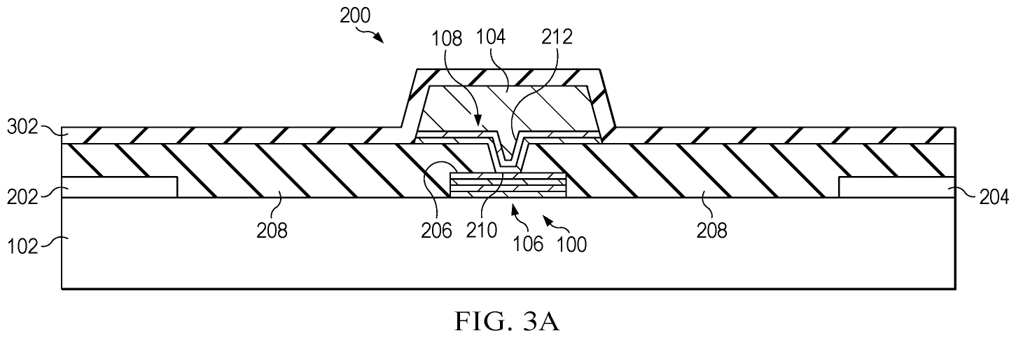

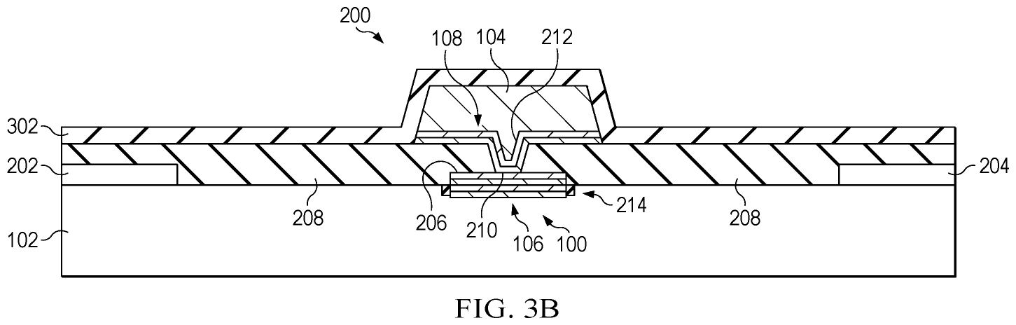

FIGS. 3A-3B illustrate examples of the dual-stage Schottky barrier 100 of FIGS. 2A-2B according to a second embodiment of this disclosure. According to the embodiment illustrated in FIGS. 3A-3B, after the gate electrode 104 is formed, a post-gate passivation layer 302 is deposited over the early passivation layer 208 and the gate electrode 104. According to some embodiments, the post-gate passivation layer 302 can include a layer of silicon nitride or other suitable material. As with the embodiment illustrated in FIG. 2A, the embodiment of FIG. 3A includes the first stage 106 of the Schottky barrier 100 being formed on top of a planarized substrate stack 102. Similarly, as with the embodiment illustrated in FIG. 2B, the embodiment of FIG. 3B includes a recess 214 formed in the substrate stack 102 and the first stage 106 of the Schottky barrier 100 being formed at least partially in the recess 214.

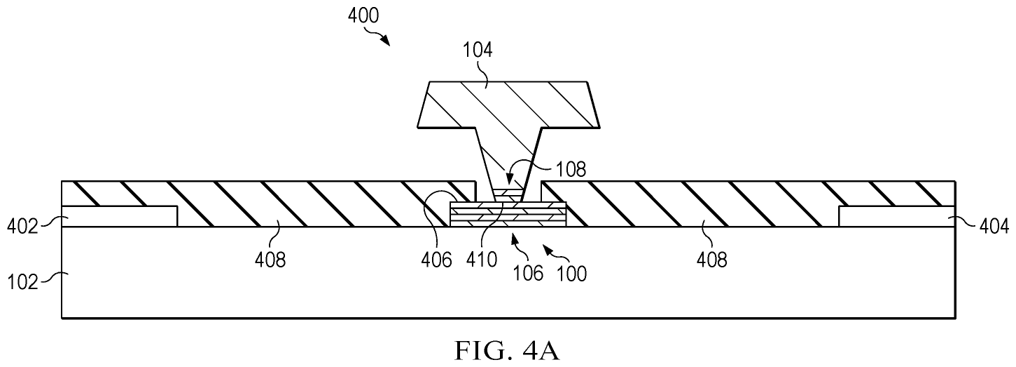

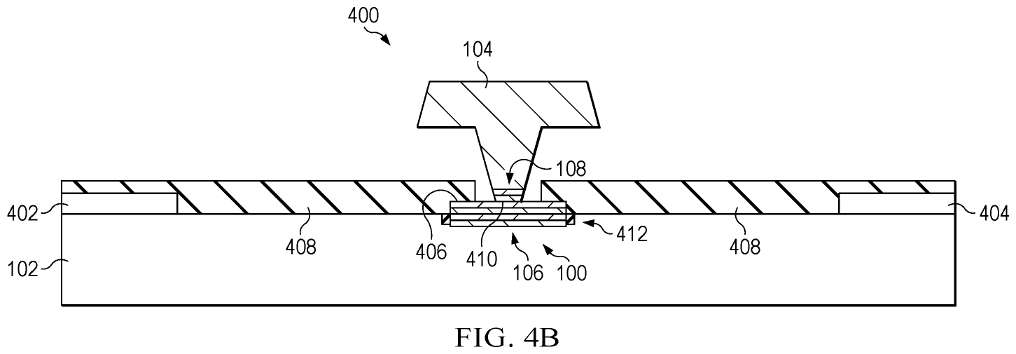

FIGS. 4A-4B illustrate examples of the dual-stage Schottky barrier 100 of FIG. 1 according to a third embodiment of this disclosure. According to the embodiment illustrated in FIGS. 4A-4B, a transistor 400 includes a source 402 and a drain 404, each formed on the substrate stack 102. The first stage 106 of the dual-stage Schottky barrier 100, including an upper layer 406, is formed over the substrate stack 102. As described above in connection with FIG. 1, the first stage 106 can include any suitable number of layers. For the particular embodiment illustrated in FIGS. 4A-4B, the first stage 106 includes four layers. Thus, for the illustrated embodiment, the fourth layer of the first stage 106 is the upper layer 406.

An early passivation layer 408 is formed over the source 402, the drain 404, and the first stage 106 of the dual-stage Schottky barrier 100. According to some embodiments, the early passivation layer 408 can include a layer of silicon nitride or other suitable material. After patterning and etching of the early passivation layer 408 to partially expose the first stage 106, the second stage 108 of the dual-stage Schottky barrier 100, including a contact segment 410, is formed over the partially exposed first stage 106.

For the particular embodiment illustrated in FIGS. 4A-4B, the second stage 108 includes two layers. However, as described above in connection with FIG. 1, the second stage 108 can include any suitable number of layers. For this embodiment, the contact segment 410 includes the entire lower layer of the second stage 108. The upper layer 406 and the contact segment 410 are configured to couple the first stage 106 and the second stage 108 together. In addition, as shown, the upper layer 406 has a length that is greater than the length of the contact segment 410.

The gate electrode 104 is formed over the second stage 108 of the dual-stage Schottky barrier 100. For the illustrated embodiment, the gate electrode 104 includes a T-shaped metal gate that may be formed on the second stage 108 via any suitable lithography technique. For some embodiments, this type of gate electrode 104 may be used for different frequency ranges of operation than the gate electrodes 104 illustrated in FIGS. 2A-2B and 3A-3B.

Thus, as the upper layer 406 of the first stage 106 is longer than the contact segment 410 of the second stage 108, even if any of the material that forms the gate electrode 104, such as gold or other suitable material, leaks past the edges of the layers of the second stage 108, the dual-stage Schottky barrier 100 prevents the material from making contact with the substrate stack 102.

For the embodiment illustrated in FIG. 4A, the first stage 106 of the Schottky barrier 100 is formed on top of a planarized substrate stack 102. However, for the embodiment illustrated in FIG. 4B, a recess 412 is formed in the substrate stack 102, and the first stage 106 of the Schottky barrier 100 is formed at least partially in the recess 412. For this embodiment, while an additional manufacturing step is introduced, the transconductance in the material can be improved.

Although FIGS. 4A-4B illustrate examples of a dual-stage Schottky barrier 100, various changes may be made to FIGS. 4A-4B. For instance, the dual-stage Schottky barrier 100 may include any suitable number of additional stages. Also, note that the views shown in FIGS. 4A-4B are not to scale. In addition, for the embodiment illustrated in FIG. 4B, it will be understood that the first stage 106 may alternatively be fully formed within the recess 412 of the substrate stack 102.

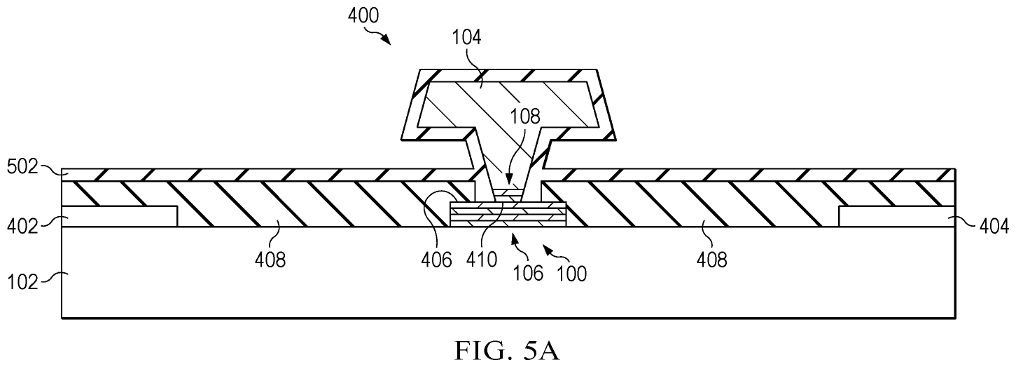

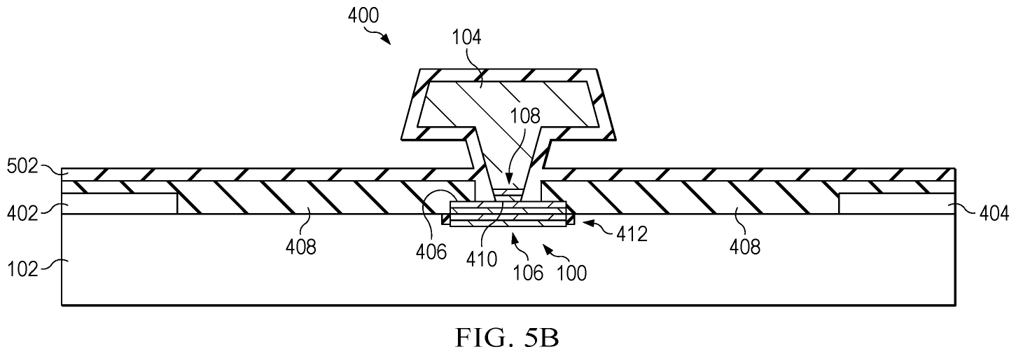

FIGS. 5A-5B illustrate examples of the dual-stage Schottky barrier 100 of FIGS. 4A-4B according to a fourth embodiment of this disclosure. According to the embodiment illustrated in FIGS. 5A-5B, after the gate electrode 104 is formed, a post-gate passivation layer 502 is deposited over the early passivation layer 408, the gate electrode 104, and a portion of the first stage 106. According to some embodiments, the post-gate passivation layer 502 can include a layer of silicon nitride or other suitable material. As with the embodiment illustrated in FIG. 4A, the embodiment of FIG. 5A includes the first stage 106 of the Schottky barrier 100 being formed on top of a planarized substrate stack 102. Similarly, as with the embodiment illustrated in FIG. 4B, the embodiment of FIG. 5B includes a recess 412 formed in the substrate stack 102 and the first stage 106 of the Schottky barrier 100 being formed at least partially in the recess 412.

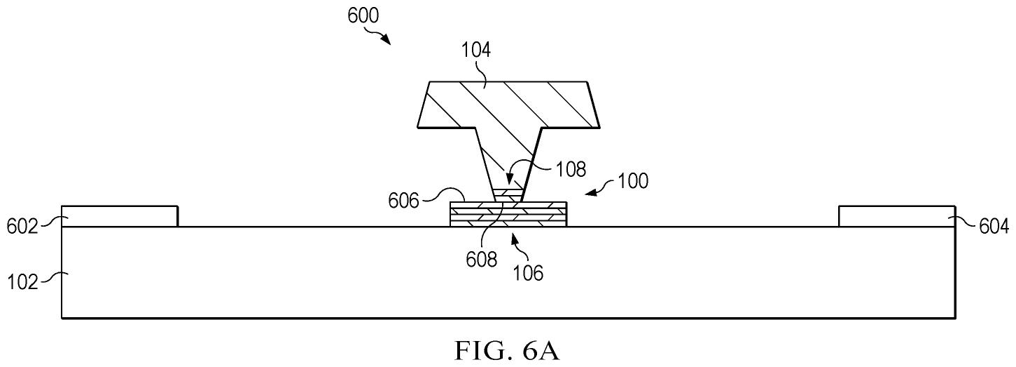

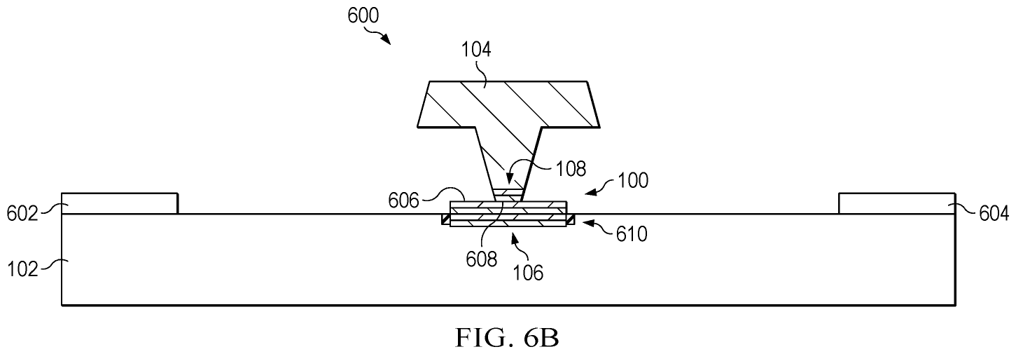

FIGS. 6A-6B illustrate examples of the dual-stage Schottky barrier of FIG. 1 according to a fifth embodiment of this disclosure. According to the embodiment illustrated in FIGS. 6A-6B, a transistor 600 includes a source 602 and a drain 604, each formed on the substrate stack 102. The first stage 106 of the dual-stage Schottky barrier 100, including an upper layer 606, is formed over the substrate stack 102. As described above in connection with FIG. 1, the first stage 106 can include any suitable number of layers. For the particular embodiment illustrated in FIGS. 6A-6B, the first stage 106 includes four layers. Thus, for the illustrated embodiment, the fourth layer of the first stage 106 is the upper layer 606.

The second stage 108 of the dual-stage Schottky barrier 100, including a contact segment 608, is formed over the first stage 106. For the particular embodiment illustrated in FIGS. 6A-6B, the second stage 108 includes two layers. However, as described above in connection with FIG. 1, the second stage 108 can include any suitable number of layers. For this embodiment, the contact segment 608 includes the entire lower layer of the second stage 108. The upper layer 606 and the contact segment 608 are configured to couple the first stage 106 and the second stage 108 together. In addition, as shown, the upper layer 606 has a length that is greater than the length of the contact segment 608.

The gate electrode 104 is formed on the second stage 108 of the dual-stage Schottky barrier 100. For the illustrated embodiment, the gate electrode 104 includes a T-shaped metal gate that may be formed on the second stage 108 via any suitable lithography technique. For some embodiments, this type of gate electrode 104 may be used for different frequency ranges of operation than the gate electrodes 104 illustrated in FIGS. 2A-2B and 3A-3B.

Thus, as the upper layer 606 of the first stage 106 is longer than the contact segment 608 of the second stage 108, even if any of the material that forms the gate electrode 104, such as gold or other suitable material, leaks past the edges of the layers of the second stage 108, the first stage 106 of the dual-stage Schottky barrier 100 prevents the material from making contact with the substrate stack 102.

For the embodiment illustrated in FIG. 6A, the first stage 106 of the Schottky barrier 100 is formed on top of a planarized substrate stack 102. However, for the embodiment illustrated in FIG. 6B, a recess 610 is formed in the substrate stack 102, and the first stage 106 of the Schottky barrier 100 is formed at least partially in the recess 610. For this embodiment, while an additional manufacturing step is introduced, the transconductance in the material can be improved.

Although FIGS. 6A-6B illustrate examples of a dual-stage Schottky barrier 100, various changes may be made to FIGS. 6A-6B. For instance, the dual-stage Schottky barrier 100 may include any suitable number of additional stages. Also, note that the views shown in FIGS. 6A-6B are not to scale. In addition, for the embodiment illustrated in FIG. 6B, it will be understood that the first stage 106 may alternatively be fully formed within the recess 610 of the substrate stack 102.

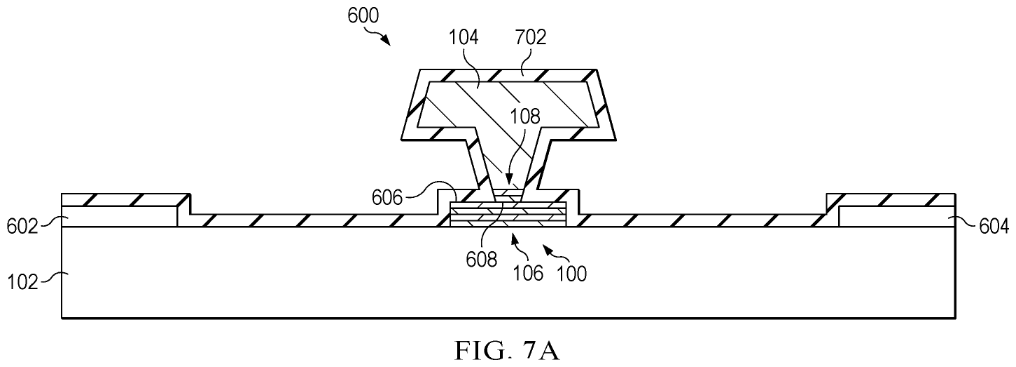

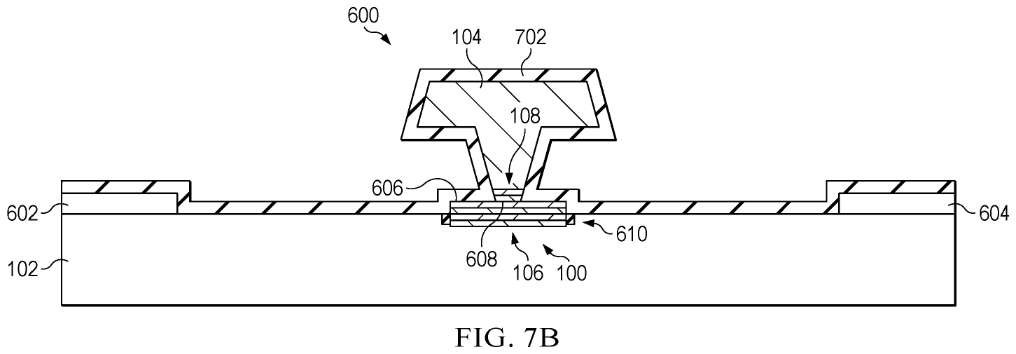

FIGS. 7A-7B illustrate examples of the dual-stage Schottky barrier 100 of FIGS. 6A-6B according to a sixth embodiment of this disclosure. According to the embodiment illustrated in FIGS. 7A-7B, after the gate electrode 104 is formed, a post-gate passivation layer 702 is deposited over the substrate stack 102, the gate electrode 104, a portion of the first stage 106, the source 602 and the drain 604. According to some embodiments, the post-gate passivation layer 702 can include a layer of silicon nitride or other suitable material. As with the embodiment illustrated in FIG. 6A, the embodiment of FIG. 7A includes the first stage 106 of the Schottky barrier 100 being formed on top of a planarized substrate stack 102. Similarly, as with the embodiment illustrated in FIG. 6B, the embodiment of FIG. 7B includes a recess 610 formed in the substrate stack 102 and the first stage 106 of the Schottky barrier 100 being formed at least partially in the recess 610.

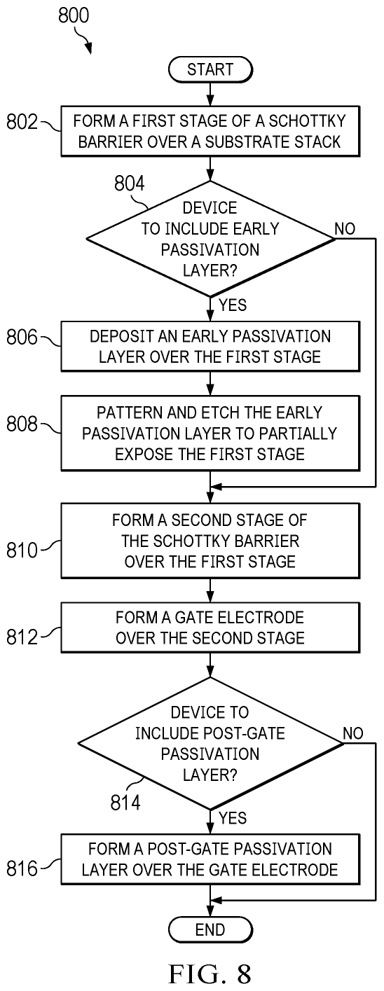

FIG. 8 illustrates an example method 800 for forming a semiconductor device, such as the transistor 200, 400 or 600, that includes the dual-stage Schottky barrier 100 according to an embodiment of this disclosure. As shown in FIG. 8, a first stage 106 of a Schottky barrier 100 is formed over a substrate stack 102 at step 802. This may include, for example, depositing, patterning, and etching one or more layers, either on a planarized substrate stack 102 or at least partially within a recess 214, 412 or 610 of a substrate stack 102. As noted above, in some cases, the first stage 106 can include four metal layers. The first stage 106 includes an upper layer 206, 406 or 606 that has a length corresponding to a gate length for the device that includes the Schottky barrier 100. For a particular embodiment, the first stage 106 can include a first layer of nickel, a second layer of platinum, a third layer of nickel, and a fourth layer of platinum. For this particular embodiment, the fourth layer of platinum is the upper layer 206, 406 or 606.

For embodiments in which the device is to include an early passivation layer 208 or 408 as shown at step 804, the early passivation layer 208 or 408 is deposited over the first stage 106 at step 806. The early passivation layer 208 or 408 may include silicon nitride. The early passivation layer 208 or 408 is patterned and etched to partially expose the first stage 106 at step 808. For some embodiments, the early passivation layer 208 may be etched without requiring thermal reflow steps to slope the sidewalls 212.

After the early passivation layer 208 or 408 is etched at step 808 or for embodiments in which the device is not to include an early passivation layer 208 or 408 at step 804, a second stage 108 of the Schottky barrier 100 is formed over the first stage 106 at step 810. This may include, for example, depositing, patterning, and etching one or more layers. As noted above, in some cases, the second stage 108 can include two metal layers. The second stage 108 includes a contact segment 210, 410 or 608 that has a length less than the length of the upper layer 206, 406 or 606 (i.e., the gate length for the device). For a particular embodiment, the second stage 108 can include a fifth layer of nickel and a sixth layer of platinum. For this particular embodiment, at least a portion of the fifth layer of nickel provides the contact segment 210, 410 or 608. For some embodiments, the second stage 108 of the Schottky barrier 100 formed at step 810 can include sidewalls 212, while for other embodiments, the second stage 108 can include planarized layers without sidewalls.

For some embodiments, the second stage 108 may be formed partially on the first stage 106 (via the contact segment 210) and also partially on the early passivation layer 208, while for other embodiments, the second stage 108 may be formed only on the first stage 106. In the latter embodiments, the entire lower layer of the second stage 108 comprises the contact segment 410 or 608.

A gate electrode 104 is formed over the second stage 108 of the Schottky barrier 100 at step 812. This may include, for example, implementing a gate metal evaporation process to complete the formation of the gate electrode 104. Alternatively, this may include forming a T-shaped metal gate on the second stage 108 via any suitable lithography technique. As noted above, in some cases the gate electrode 104 can be formed from gold.

For embodiments in which the device is to include a post-gate passivation layer 302, 502 or 702 as shown at step 814, the post-gate passivation layer 302, 502 or 702 is formed over the gate electrode 104 at step 816. In addition to the gate electrode 104, for some embodiments, the post-gate passivation layer 302, 502 or 702 may also be formed over the early passivation layer 208 or 408 and/or the first stage 106 of the dual-stage Schottky barrier 100. The post-gate passivation layer 302, 502 or 702 may include silicon nitride. After the post-gate passivation layer 302, 502 or 702 is formed at step 816 or for embodiments in which the device is not to include a post-gate passivation layer 302, 502 or 702 at step 814, the method comes on an end.

Because the length of the contact segment 210, 410 or 608 is less than the length of the upper layer 206, 406 or 606, if any material of the gate electrode 104 leaks through or past the contact segment 210, 410 or 608 of the second stage 108, the upper layer 206, 406 or 606 of the first stage 106 blocks the leak so that the material is unable to make contact with the substrate stack 102. This method reduces sensitivity to sidewall angles, roughened edges, and nitride etch defects that could lead to yield loss. In this way, gate leakage can be minimized or eliminated, and the lifetime of the device can be increased. In addition, by forming the first stage 106 prior to the second stage 108 of the Schottky barrier 100, etch damage to the substrate stack 102 may be avoided when the early passivation layer 208 or 408 is etched.

Although FIG. 8 illustrates one example of a method 800 for forming a dual-stage Schottky barrier 100, various changes may be made to FIG. 8. For example, it will be understood that each of the first stage 106 and the second stage 108 may include any suitable number of layers and that the layers may each comprise any suitable material. In addition, it will be understood that each of the gate electrode 104, the early passivation layer 208 or 408, and the post-gate passivation layer 302, 502 or 702 may comprise any suitable material.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A semiconductor device comprising:
a dual-stage Schottky barrier, wherein the dual-stage Schottky barrier comprises:
a first stage formed over a substrate stack, wherein the first stage comprises an upper layer having a length corresponding to a gate length for the device; and
a second stage formed at least partially over the first stage, wherein the second stage comprises a contact segment having a length less than the gate length.

2. The semiconductor device of claim 1, wherein each of the first stage and the second stage comprises a plurality of metal layers.

3. The semiconductor device of claim 1, wherein:
the first stage comprises a first layer, a second layer, a third layer, and a fourth layer, wherein the upper layer comprises the fourth layer;
the second stage comprises a fifth layer and a sixth layer, wherein the contact segment comprises at least a portion of the fifth layer;
each of the first layer, the third layer, and the fifth layer comprises nickel; and
each of the second layer, the fourth layer, and the sixth layer comprises platinum.

4. The semiconductor device of claim 1, further comprising a T-shaped metal gate formed over the second stage.

5. The semiconductor device of claim 1, further comprising an early passivation layer formed over the first stage.

6. The semiconductor device of claim 5, wherein:
the second stage comprises sidewalls; and
the device further comprises a gate electrode formed over the second stage.

7. The semiconductor device of claim 5, further comprising a T-shaped metal gate formed over the second stage.

8. The semiconductor device of claim 5, further comprising:
a gate electrode formed over the second stage; and
a post-gate passivation layer formed over the early passivation layer and the gate electrode.

9. The semiconductor device of claim 1, further comprising:
a gate electrode formed over the second stage; and
a post-gate passivation layer formed over the gate electrode.

10. The semiconductor device of claim 1, wherein:
the substrate stack comprises a recess; and
the first stage is formed at least partially in the recess of the substrate stack.

11. A method comprising:
forming a first stage of a dual-stage Schottky barrier over a substrate stack for a semiconductor device, wherein the first stage comprises an upper layer having a length corresponding to a gate length for the device; and
forming a second stage of the dual-stage Schottky barrier at least partially over the first stage, wherein the second stage comprises a contact segment having a length less than the gate length.

12. The method of claim 11, further comprising forming a gate electrode over the second stage.

13. The method of claim 12, further comprising forming a post-gate passivation layer over the gate electrode.

14. The method of claim 11, wherein each of the first stage and the second stage comprises a plurality of metal layers.

15. The method of claim 11, wherein:
forming the first stage of the dual-stage Schottky barrier comprises forming a first layer, a second layer, a third layer, and a fourth layer, wherein the upper layer comprises the fourth layer;
forming the second stage of the dual-stage Schottky barrier comprises forming a fifth layer and a sixth layer, wherein the contact segment comprises at least a portion of the fifth layer;
each of the first layer, the third layer, and the fifth layer comprises nickel; and
each of the second layer, the fourth layer, and the sixth layer comprises platinum.

16. A method comprising:
forming a first stage of a dual-stage Schottky barrier over a substrate stack for a semiconductor device, wherein the first stage comprises an upper layer having a length corresponding to a gate length for the device;
forming an early passivation layer over the first stage;
patterning and etching the early passivation layer to partially expose the first stage; and
forming a second stage of the dual-stage Schottky barrier at least partially over the first stage, wherein the second stage comprises a contact segment having a length less than the gate length.

17. The method of claim 16, further comprising forming a gate electrode over the second stage.

18. The method of claim 17, further comprising forming a post-gate passivation layer over the gate electrode.

19. The method of claim 16, wherein each of the first stage and the second stage comprises a plurality of metal layers.

20. The method of claim 16, wherein:
forming the first stage of the dual-stage Schottky barrier comprises forming a first layer, a second layer, a third layer, and a fourth layer, wherein the upper layer comprises the fourth layer;
forming the second stage of the dual-stage Schottky barrier comprises forming a fifth layer and a sixth layer, wherein the contact segment comprises at least a portion of the fifth layer;
each of the first layer, the third layer, and the fifth layer comprises nickel; and
each of the second layer, the fourth layer, and the sixth layer comprises platinum.
